(19) United States
(12) Patent Application Publication
(10) Pub. No.: US 2010/0207202 A1
(43) Pub. Date: Aug. 19, 2010

(54) SEMICONDUCTOR DEVICE AND METHOD OF MANUFACTURING THE SAME

(75) Inventor: Yasuhiko UEDA, Tokyo (JP)

Correspondence Address: YOUNG & THOMPSON, 209 Madison Street, Suite 500, Alexandria, VA, 22314, US

(73) Assignee: ELPIDA MEMORY, INC, Tokyo (JP)

(21) Appl. No.: 12/706,501

(22) Filed: Feb. 16, 2010

(30) Foreign Application Priority Data
Feb. 17, 2009 (JP) 2009-034048

(51) Int. Cl. H01L 29/78; H01L 21/336

(52) U.S. Cl. 257/329; 438/268; 438/585; 257/E29.262; 257/E21.41

(57) ABSTRACT

A semiconductor device includes a semiconductor substrate, a first insulating film, a second insulating film, and a conductive layer. The semiconductor substrate includes a pillar portion extending from a main surface of the semiconductor substrate. The first insulating film covers a side surface of the pillar portion. The second insulating film covers the main surface of the semiconductor substrate. The second insulating film is thicker than the first insulating film. The conductive layer extends along the first insulating film.

### BACKGROUND OF THE INVENTION

1. Field of the Invention

The present invention relates to a semiconductor device and a method of manufacturing the same.

Priority is claimed on Japanese Patent Application No. 2009-034048, filed Feb. 17, 2009, the content of which is incorporated herein by reference.

2. Description of the Related Art

Recently, miniaturization of MOS transistors included in an integrated circuit is required with rapid progress of higher integrated circuits. Vertical MOS transistors (pillar transistors) have been proposed as miniaturized MOS transistors. Regarding a vertical MOS transistor, a gate electrode is formed on a side surface of a pillar semiconductor.

Japanese Patent Laid-Open Publication No. H05-136374 discloses a semiconductor device and a method of manufacturing the same. The semiconductor device includes: an insulating gate transistor including a pillar semiconductor region on a main surface side of a semiconductor substrate, a gate electrode covering a side surface of the pillar semiconductor region through a gate insulating film, and main electrode regions above and below the pillar semiconductor region; and a memory element on the upper main electrode region, which can be electrically broken.

Japanese Patent Laid-Open Publication No. H08-195381 discloses a method of manufacturing a semiconductor device in which a silicon oxide film is etched using an etching gas containing an HF gas, the etching gas including a gas for increasing pH.

Japanese Patent Laid-Open Publication No. 2007-134562 discloses a solid imaging apparatus and a method of manufacturing the same. The solid imaging apparatus includes: a semiconductor substrate including a substrate main body and a protruding portion protruding from the substrate main body; a photodiode included in the protruding portion; a reading gate facing at least a part of a side surface of the protruding portion. A detail of a gate processing method is explained in FIGS. 3 to 7.

Suguru Saito, Yoshiya Hagimoto, Hayato Iwamoto, Yusuke Muraki, Proceedings of the 55th Meeting (2008) of The Japan Society of Applied Physics and Related Societies, No. 2, 27p-ZR-1, p. 829 relates to an evaluation of a plasmaless etching process using gas reaction and discloses a method of forming a pillar portion on a semiconductor substrate using plasmaless etching.

Generally, a gate electrode of a vertical MOS transistor is formed by etching a conductive film formed so as to cover a side surface of a pillar portion vertically extending from a substrate.

As explained above, however, the pillar portion has been getting thinner and longer as the vertical MOS transistors have recently been formed in a miniaturized region. In other words, the aspect ratio of the space between two adjacent pillar portions to the height of the pillar portion has been increasing.

Since the space between two adjacent pillar portions in a region where the pillar portions are densely formed is narrower than before, it is difficult for etching ions to pass through the space and reach a bottom of the pillar potion, thereby decreasing the etching rate of the conductive film covering the lower side surface of the pillar portion.

If the conductive film between the two adjacent pillar portions in the dense region is to be completely removed, the conductive film in a region where pillar portions are sparsely formed is over-etched. In other words, a gate oxide film and a substrate under the conductive film are etched, thereby making the main surface of the substrate uneven, and therefore causing junction leakage in an impurity diffusion layer, and causing foreign matter to be included.

### SUMMARY

In one embodiment, a semiconductor device may include, but is not limited to, a semiconductor substrate, a first insulating film, a second insulating film, and a conductive layer. The semiconductor substrate includes a pillar portion extending from a main surface of the semiconductor substrate. The first insulating film covers a side surface of the pillar portion. The second insulating film covers the main surface of the semiconductor substrate. The second insulating film is thicker than the first insulating film. The conductive layer extends along the first insulating film.

In another embodiment, a semiconductor device may include, but is not limited to, a semiconductor substrate, a first insulating film, a conductive layer, and a second insulating film. The semiconductor substrate includes a pillar portion extending from a main surface of the semiconductor substrate. The first insulating film covers a side surface of the pillar portion. The conductive layer extends along the first insulating film. The second insulating film covers the main surface of the semiconductor substrate. The second insulating film immediately under the conductive layer and the first insulating film includes first and second insulating portions. The first insulating portion is thicker than the second insulating portion. The second insulating portion is between the pillar portion and the first insulating portion.

In still another embodiment, a method of manufacturing a semiconductor device may include, but is not limited to, the following processes. A semiconductor substrate is etched to form a pillar portion extending from a main surface of the etched semiconductor substrate. Then, first and second insulating films are formed. The first insulating film covers a side surface of the pillar portion. The second insulating film covers the main surface of the etched semiconductor substrate. The second insulating film is thicker than the first insulating film. Then, a conductive film is formed so as to cover the first and second insulating films. Then, the conductive film is etched to form a conductive layer extending along the first insulating film.

Accordingly, the conductive film can be formed without etching the main surface of the semiconductor substrate in a sparse region where multiple pillar portions are sparsely formed, thereby stabilizing the transistor characteristics.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a plane view illustrating an example of a semiconductor device according to a first embodiment of the present invention;

FIG. 1B is a cross-sectional view taken along a line A-A′ shown in FIG. 1A;

FIGS. 2A and 2B are enlarged views illustrating portions B and C shown in FIG. 1B, respectively;

FIGS. 3 to 14 are cross-sectional views indicative of a process flow illustrating a method of manufacturing the semiconductor device according to the first embodiment, in which FIGS. 8B, 13A, and 13B are enlarged views illustrating a portion D shown in FIG. 8A, and portions E and F shown in FIG. 12, respectively;

FIG. 15 is a cross-sectional view illustrating an example of a semiconductor device according to a second embodiment of the present invention;

FIG. 16 is a cross-sectional view illustrating an example of a semiconductor device according to a third embodiment of the present invention;

FIGS. 17 to 21 are cross-sectional views indicative of a process flow illustrating a method of manufacturing the semiconductor device according to the third embodiment;

FIG. 22 is a cross-sectional view illustrating an example of a semiconductor device according to a fifth embodiment of the present invention;

FIG. 23 is a cross-sectional view illustrating an example of a semiconductor device according to a sixth embodiment of the present invention; and

FIGS. 24 and 25 are cross-sectional views illustrating comparison examples regarding a semiconductor device manufacturing method.

### DETAILED DESCRIPTION OF THE PREFERRED EMBODIMENTS

The present invention will now be described herein with reference to illustrative embodiments. The accompanying drawings explain a semiconductor device and a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

### First Embodiment

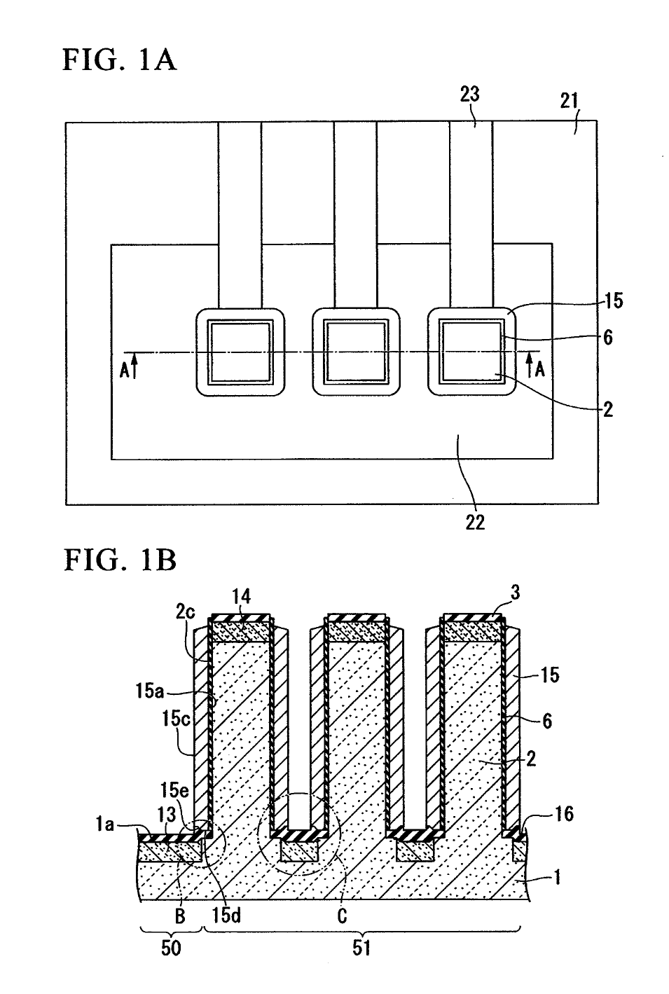

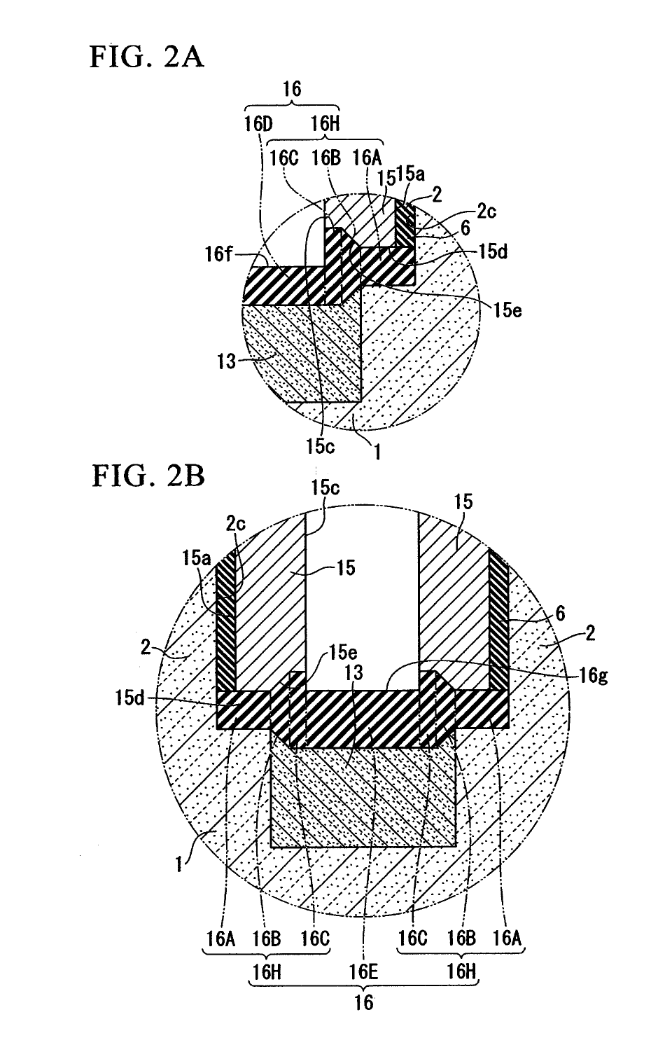

FIG. 1A is a plane view illustrating an example of a semiconductor device according to a first embodiment of the present invention in a state where a conductive layer (gate electrode) of a vertical MOS transistor has been formed. FIG. 1B is a cross-sectional view taken along a line A-A′ shown in FIG. 1A. FIGS. 2A and 2B are enlarged views illustrating portions B and C shown in FIG. 1B, respectively.

As shown in FIG. 1A, the semiconductor device of the first embodiment includes: an active region 22 of a substrate 1, which is substantially rectangular when viewed in a direction perpendicular to a main surface of the substrate 1 (hereinafter, “plane view”); and an element isolation region 21 surrounding the active region 22.

Three pillar portions 2, which are substantially square in plane view, are aligned in a line in the active region 22. A first insulating film (gate insulating film) 6 is formed so as to surround each of the pillar portions 2. A conductive layer 15 is formed so as to surround the first insulating film 6. A gate wire 23 is connected to the conductive layer 15 and drawn from the active region 22 to the element isolation region 21.

As shown in FIG. 1B, the semiconductor device of the first embodiment includes the substrate 1 and the pillar portion 2 protruding from a main surface 1a of the substrate 1. The pillar portion 2 has a side surface 2c covered by the first cylindrical insulating film 6 covered by the cylindrical conductive layer 15, and serves as a channel.

An n-type or p-type impurity ion is doped into an upper region of each pillar portion 2 to form an activated impurity diffusion region 14. An oxide film 3 is formed so as to cover the upper surface of the pillar portion 2. The activated impurity diffusion region 14 is connected to a power source (not shown).

An n-type or p-type impurity ion is doped into the substrate 1 immediately under the surface 1a thereof on the bottom side of the pillar 2 to form activated impurity diffusion regions 13. The activated impurity diffusion regions 13 are connected to another power source (not shown). Thus, a vertical MOS transistor is formed.

The substrate 1 and the pillar 2 are made of a semiconductor material, such as silicon (Si) or germanium (Ge). An n-type or p-type impurity ion may be doped therein.

The first insulating film 6 is used as a gate oxide film and made of a silicon oxide film (SiO₂), a germanium oxide film, or the like. The oxide film 3 is a film for protecting an upper end of the pillar 2 and made of a silicon oxide film (SiO₂), or the like.

The conductive layer 15 is used as a gate electrode and made of polysilicon, metal, alloy, or the like. The conductive layer 15 includes an inner portion 15a on the side of the pillar 2, an outer portion 15c on the opposite side of the pillar 2, and a bottom portion 15d on the side of the substrate 1. The bottom portion 15d includes a taper portion 15e slanting downward toward the pillar 2.

Accordingly, the substrate 1 is insulated from the conductive layer 15, thereby preventing junction leakage in the impurity diffusion regions, preventing field concentration on the bottom side of the conductive layer 15, and therefore enhancing the reliability of the transistor.

As shown in FIG. 1B, the semiconductor device of the first embodiment has a region 50 where the pillars 2 are sparsely formed (hereinafter, “sparse region 50”), and a region 51 where the pillars 2 are densely formed (hereinafter, “dense region 51”). The dense region 51 indicates a region including at least two pillar portions 2 that are closely spaced.

A second insulating film 16 is formed so as to cover the surface 1a of the substrate 1. The second insulating film 16 is connected to the bottom portion of the first insulating film 6 covering the side surface 2c of the pillar portion 2. The second insulating film is made of a silicon oxide film (SiO₂) or the like.

As shown in FIG. 2A, the second insulating film 16 includes a thick film portion 16H and a thin film portion 16D in the sparse region 50. Preferably, the thick film portion 16H is thicker than the first insulating film 6. The thick film portion 16H surrounds the bottom portion of the pillar portion 2.

Accordingly, the substrate 1 is insulated from the conductive layer 15, thereby preventing junction leakage in the impurity diffusion regions, preventing field concentration on the bottom side of the conductive layer 15, and therefore enhancing the reliability of the transistor.

The thin film portion 16D has a substantially even thickness over the surface 1a of the substrate 1. One end of the thin film portion 16D is connected to the thick film portion 16H, and thus a recessed portion 16f is formed.

The thick film portion 16H includes first to third thick film elements 16C, 16B, and 16A. The first thick film element 16C has an even thickness, is the thickest among the first to third thick film elements, and is connected to the second thick film element 16B.

The thickness of the first thick film element 16C is, for example, approximately 30 nm. As will be explained later regarding a method of manufacturing the semiconductor device, even if the thickness of the first thick film element 16C is increased by decreasing the thickness of the recessed portion 16f, the main surface 1a of the substrate 1 is not exposed. Accordingly, the surface 1a of the substrate 1 can be protected, thereby stabilizing the characteristics of the transistor.

The second thick film element 16B is gradually thinner toward the pillar 2, and connects to the third thick film element 16A. The second thick film element 16B has upper and lower sloping portions that are sloped at the substantially same angle. The upper and lower sloping portions may be sloped at different angles.

The third thick film element 16A has a substantially even thickness, and is connected to the first insulating film 6. The cross-sectional shape of the second insulating film 16 is called a bird's beak shape since the second insulating film 16 is thicker toward the side of the first thick film element 16C and thinner toward the side of the third thick film element 16A.

As shown in FIG. 2B, the second insulating film 16 includes the thick film portion 16H and another thin film portion 16E in the dense region 51. The thin film portion 16E has a substantially even thickness over the surface 1a of the substrate 1. Both sides of the thin film portion 16E are connected to the thick film portions 16H, and thus a recessed portion 16g is formed. The thin film portion 16E is thicker than the thin film portion 16D.

Similar to the thick film portion 16H in the dense region 50, the thick film portion 16H in the dense region 51 includes first to third thick film elements 16C, 16B, and 16A. The thick film portion 16H surrounds the bottom portion of the pillar portion 2.

Accordingly, the substrate 1 is insulated from the conductive layer 15, thereby preventing junction leakage in the impurity diffusion regions, preventing field concentration on the bottom side of the conductive layer 15, and therefore enhancing the reliability of the transistor.

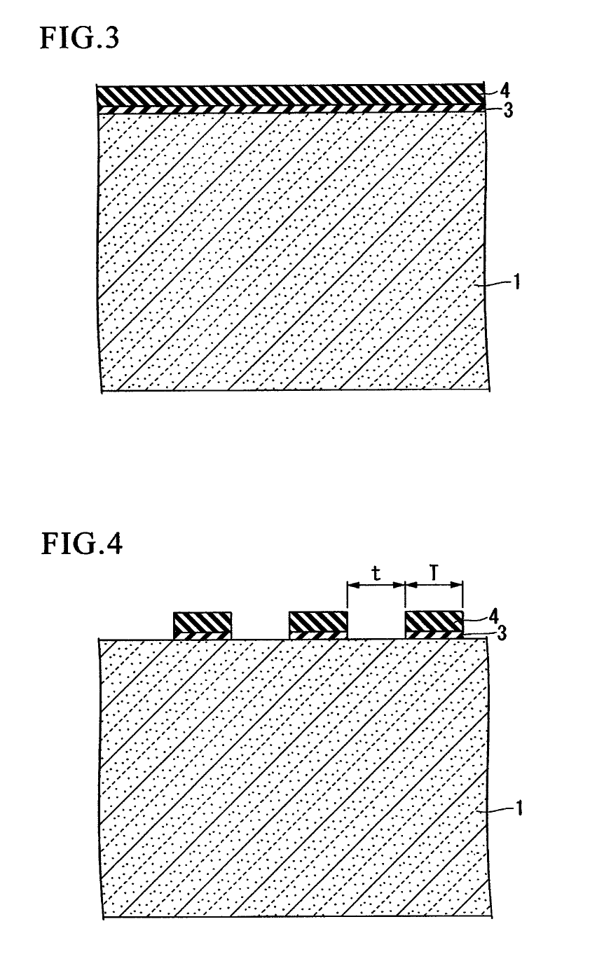

Hereinafter, a method of manufacturing the semiconductor device of the first embodiment is explained with reference to FIGS. 3 to 14, which are cross-sectional views taken along the line A-A′ shown in FIG. 1.

The method of manufacturing the semiconductor device of the first embodiment mainly includes first to eight processes. In the first process, a semiconductor substrate having a main surface is etched to form a pillar portion vertically extending from the main surface, the pillar portion being made of the semiconductor material. In the second process, a third insulating film is formed so as to cover a side surface of the pillar portion and the main surface of the semiconductor substrate. In the third process, a fourth insulating film is formed so as to cover the third insulating film, and then the fourth insulating film is etched to form a sidewall portion. In the fourth process, the main surface of the semiconductor substrate is oxidized through the third insulating film using the sidewall portion as a mask to prevent the side surface of the pillar portion from being oxidized, and thus a fifth insulating film including the third insulating film and the oxide film is formed on the main surface of the semiconductor substrate. In the fifth process, the sidewall portion is removed. In the sixth process, the third insulating film covering the side surface of the pillar portion is etched to be removed while the fifth insulating film remains on the main surface of the semiconductor substrate. In the seventh process, the first insulating film is formed so as to cover the side surface of the pillar portion and the fifth insulating film, and thus the second insulating film including the first and fifth insulating films is formed on the main surface of the semiconductor substrate. In the eighth process, a conductive film is formed so as to cover the first insulating film, and then the conductive film is etched to form a conductive layer covering the side surface of the pillar portion and the semiconductor substrate.

Hereinafter, the first to eighth processes are explained in detail. In the first process, the oxide film 3 made of silicon is formed on the substrate 1. For example, a thermal oxide film formed by heating in H₂—O₂ atmosphere at approximately 850° C. is used as the oxide film 3. The thickness of the oxide film 3 is, for example, 10 nm.

Then, a nitride film 4 is formed over the oxide film 3 using, for example, LPCVD (Low Pressure Chemical Vapor Deposition), as shown in FIG. 3. The thickness of the nitride film 4 is, for example, 30 nm.

Then, a pillar portion of a vertical MOS transistor is formed by photolithography and etching. Specifically, a mask for forming the pillar portion, such as a resist mask, is formed over the oxide film 3.

Then, etching is carried out using the mask to pattern the oxide film 3 and the nitride film 4 shown in FIG. 4. The horizontal width T of the patterned portion and the distance t between two adjacent patterned portions are, for example, 50 nm. Although not shown in FIG. 4, the oxide film 3 and the nitride film 4 are patterned so as to be substantially square in plane view.

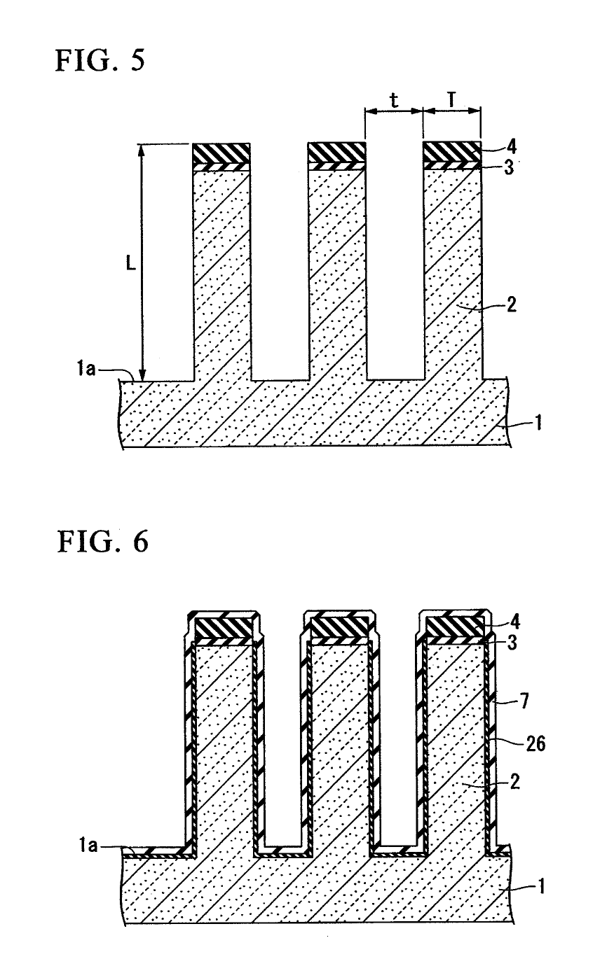

Then, the substrate 1 is etched in the thickness of, for example, 200 nm, using the nitride mask 4 as a hard mask to form three substantially-square pillar portions 2 protruding from the surface 1a of the substrate 1, as shown in FIG. 5. The three pillar portions 2 are aligned in a straight line in plane view. Since the distance t between two adjacent pillar portions 2 is 50 nm, and the height L of the pillar portion 2 is 200 nm, the height L divided by the distance t is 4.

In the second process, a third insulating film 26 is formed so as to cover the side surface 2c of the pillar portion 2 and the surface 1a of the substrate 1. The third insulating film 26 is made of a silicon oxide film (SiO₂) or the like, and is used as a pad insulating film that will be completely removed in the end. For example, a thermal oxide film formed by heating in H₂—O₂ atmosphere at approximately 850° C., or a CVD oxide film formed by CVD (Chemical Vapor Deposition) is used as the third insulating film 26. The thickness of the third insulating film 26 is, for example, 5 nm.

In the third process, a fourth insulating film 7 is formed so as to cover the third insulating film 26 covering the surface 1a of the substrate 1 and the side surface 2c of the pillar portion 2, and the nitride film 4 covering the upper surface of the pillar portion 2.

The fourth insulating film 7 is made of a silicon nitride film (SiN) or the like, and is used as a protection insulating film. For example, an LPCVD nitride film formed by LPCVD is used as the fourth insulating film 7. The thickness of the fourth insulating film 7 is, for example, 10 nm.

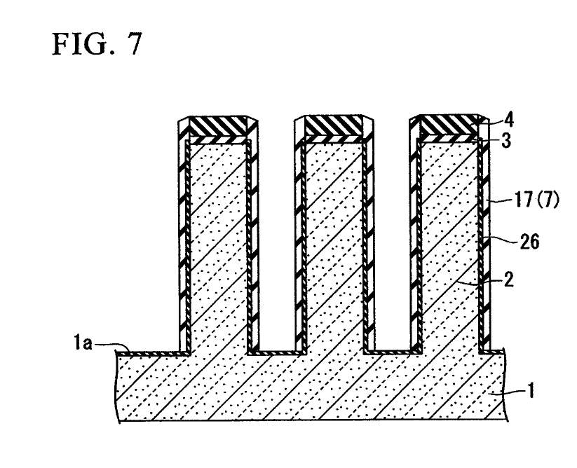

Then, the fourth insulating film 7 is anisotropically etched until the third insulating film on the surface 1a of the substrate 1 is exposed. Thus, only the fourth insulating film 7 covering the side surface 2c of the pillar portion 2 remains to form a sidewall 17 as shown in FIG. 7. The sidewall 17 is thinner than the first insulating film 6 that will be formed in a later process. Although the third insulating film 26 on the surface 1a of the substrate 1 is remained, the third insulating film 26 may be completely removed in this process.

In the fourth process, the surface 1a of the substrate 1 under the third insulating film 26 is thermally oxidized in H₂—O₂ atmosphere at approximately 850° C. If a thermal oxide film having a thickness of, for example, approximately 30 nm is formed, a variation of a film thickness in a wafer can be prevented. Accordingly, etching can be evenly carried out in a later process.

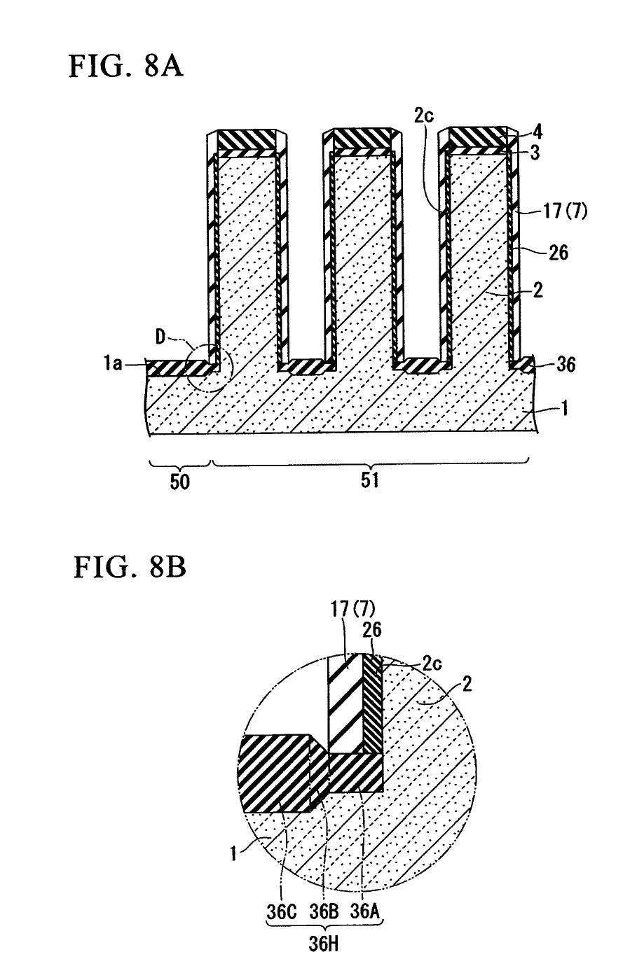

Thus, a fifth insulating film 36 including the third insulating film 26 and the thermal oxide film formed by oxidizing the surface 1a of the substrate 1 is formed as shown in FIG. 8A. The fifth insulating film 36 is formed by thermally oxidizing the surface 1a of the substrate 1 in an even thickness so as to dig the substrate 1. The larger the thickness of the fifth insulating film 36 is, the deeper the substrate 1 is dug. The thermal oxidization proceeds from the side closer to air.

Thanks to the sidewall 17 covering the side surface 2c of the pillar portion 2, the surface 1a of the substrate 1, which is close to the pillar portion 2, is hardly oxidized. For this reason, the fifth insulating film 36 has a bird's beak shape, i.e., the fifth insulating film 26 is gradually thinner toward the pillar portion 2, as shown in FIG. 8.

Thanks to the sidewall 17 and the nitride film 4, the upper and side portions of the pillar portion 2 are not oxidized. The fifth insulating film 36 is formed both in the sparse and dense regions 50 and 51, as shown in FIG. 8A.

FIG. 8B is an enlarged view illustrating a portion D shown in FIG. 8A. As shown in FIGS. 8A and 8B, the fifth insulating film 36 includes a thick film portion 36H in the sparse region 50.

Preferably, the thick film portion 36H is thicker than the fourth insulating film 7, i.e., the sidewall 17. Accordingly, even if the thick film portion 36H is etched in a later process, the surface 1a of the substrate 1 is not exposed, thereby protecting the surface 1a of the substrate 1, and therefore stabilizing the characteristics of the transistor.

The thick film portion 36H includes fourth to sixth thick film elements 36C, 36B, and 36A. The fourth thick film element 36C is the thickest among the fourth to sixth thick film elements 36C, 36B, and 36A. The fourth thick film element 36C has an even thickness of, for example, 30 nm, and is connected to the fifth thick film element 36B.

Due to further miniaturization of semiconductor devices, if a thermal oxide film having a thickness of 30 nm or more is formed in 30 nm or less space between two adjacent pillar portions 2 after the sidewall 17 is formed, it causes defects of the substrate 1. For this reason, the thickness of the fifth insulating film 36 is preferably 30 nm or less. The fifth thick film element 36B is gradually thinner toward the pillar portion 2 and connects to the sixth thick film element 36A.

The sixth thick film element 36A has substantially an even thickness, and is connected to the third insulating film 26. The sixth thick film element 36A mainly includes the third insulating film 26 and the thin thermal oxide film. The sixth thick film element 36A is thicker than the third insulating film 26.

The fifth thick film element 36B is a sloping film portion of the fifth insulating film 36, and includes the third insulating film 26 and a thermal oxide film formed by unevenly thermally oxidizing the surface 1a of the substrate.

Due to the sidewall 17, it is difficult to thermally oxidize the surface 1a of the substrate, which is close to the sidewall 17. For this reason, the degree of thermal oxidization continuously varies, and thereby the sloping film portion that is gradually thinner toward the pillar portion 2 is formed.

The illustrated structure of the fifth insulating film 36 is just an example. Alternatively, for example, the fifth thick film element 36B may not be formed so that only the fourth thick film element 36C and the sixth thick film element 36A form the fifth insulating film 36.

Even when the third insulating film 26 on the surface 1a of the substrate 1 is etched and removed in the previous process, the fifth insulating film 36 having the bird's beak shape as shown in FIG. 8 can be formed. In this case, the fifth insulating film 36 includes only a thermal oxide film.

In the fifth process, the sidewall 17 covering the side surface 2c of the pillar portion 2 is removed. When the fourth insulating film 7 made of a nitride film is used as the sidewall 17, the sidewall 17 can be removed by using phosphorus or the like. Although the nitride film 4 covering the top surface of the pillar portion 2 remains, the nitride film 4 may be removed together with the sidewall 17.

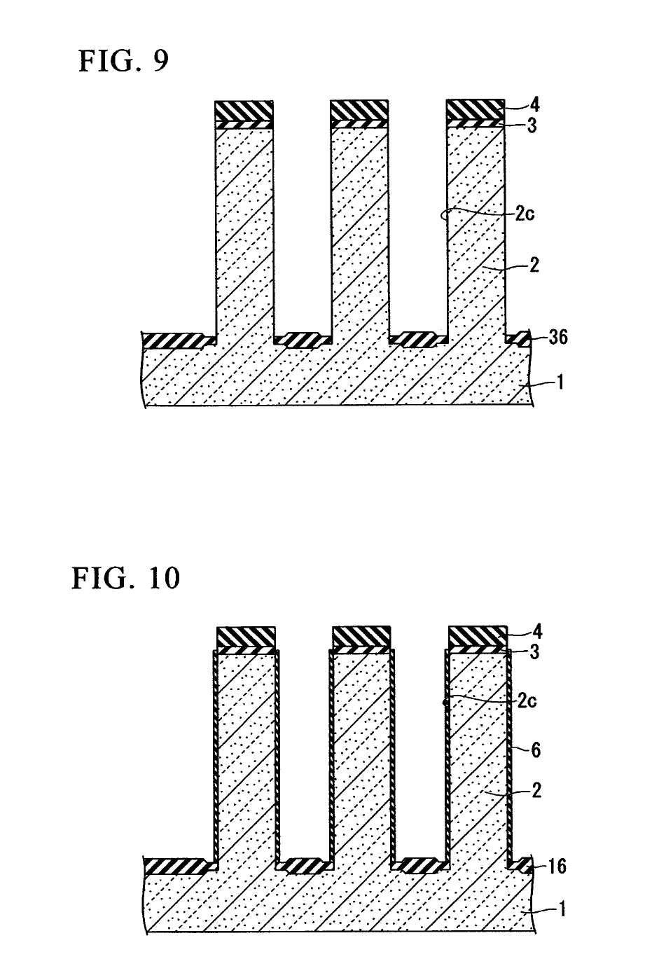

In the sixth process, the third insulating film 26 covering the side surface 2c of the pillar portion 2 is removed by a dry etching process (chemical dry etching or chemical vapor dry etching) as shown in FIG. 9. The dry etching process includes first and second reaction processes. In the first reaction process, a gas reacts with a silicon oxide to generate a silicon compound. In the second reaction process, the silicon compound is decomposed and removed by a thermal treatment.

For example, in the first reaction process, HF gas and NH₃ gas react with each other to generate NH₄F gas, and then the NH₄F gas reacts with SiO₂ to generate (NH₄)₂SiF₆. In the second reaction process, (NH₄)₂SiF₆ is decomposed into NH₃, HF, and SiF₄, which are volatilized and removed. Thus, the third insulating film 26 made of the silicon oxide film (SiO₂) covering the side surface 2c of the pillar portion 2 can be removed. In this case, the silicon oxide can be etched with a constant etching rate by using the etching process.

At the same time, the fifth insulating film 36 covering the surface 1a of the substrate 1 is also etched. However, the fifth insulating film 36 is thicker than the third insulating film 26, and therefore remains on the substrate 1 even if the third insulating film 26 is completely removed.

In the first embodiment, the thickness of the third insulating film 26 is approximately 5 nm, and the thickness of the fourth thick film element 36C of the fifth insulating film 36 is approximately 30 nm. For this reason, even if 100% over-etching of the third insulating film 26 is carried out, the fifth insulating film 36 including the fourth thick film element 36C having a thickness of approximately 20 nm can remain.

If the third insulating film 26 is formed by CVD or the like, the thicker fifth insulating film 36 can remain. This is because a thermal oxide film is more difficult to etch than a CVD oxide film formed by CVD, and the etching rate of the thermal oxide film is smaller than that of the CVD oxide film. If wet etching is used, the etching rate of the thermal oxide film further decreases, and thereby a much thicker fifth insulating film 36 can remain.

In the seventh process, the first insulating film 6 is formed so as to cover the side surface 2c of the pillar portion 2 as shown in FIG. 10. The first insulating film 6 is a gate insulating film made of a silicon oxide film (SiO₂) or the like. For example, a thermal oxide film formed by heating in H₂—O₂ atmosphere at approximately 750° C., an ALD insulating film formed by ALD (Atomic Layer Deposition), or a CVD insulating film formed by CVD may be used as the first insulating film 6. A High-K insulating film (HfSiON or the like) formed by ALD may be used as the ALD insulating film. The thickness of the first insulating film 6 is, for example, approximately 3 nm.

The first insulating film 6 is deposited on the fifth insulating film 36, and thus the second insulating film 16 is formed. When the first insulating film 6 is formed by thermally oxidizing the side surface 2c of the pillar portion 2, the surface 1a of the substrate 1 is also oxidized, and thus the second insulating film 16 is formed.

Also when the first insulating film 6 is formed by forming, on the side surface 2c of the pillar portion 2, a High-K insulating film formed by ALD, the High-K insulating film is deposited over the fifth insulating film 36, and thus the second insulating film 16 is formed.

In other words, whether the thermal oxide film or High-K insulating film is used as the first insulating film 6, the fifth insulating film 36 and the first insulating film 6 form the second insulating film 16. The thickness of the second insulating film is, for example, approximately 23 nm.

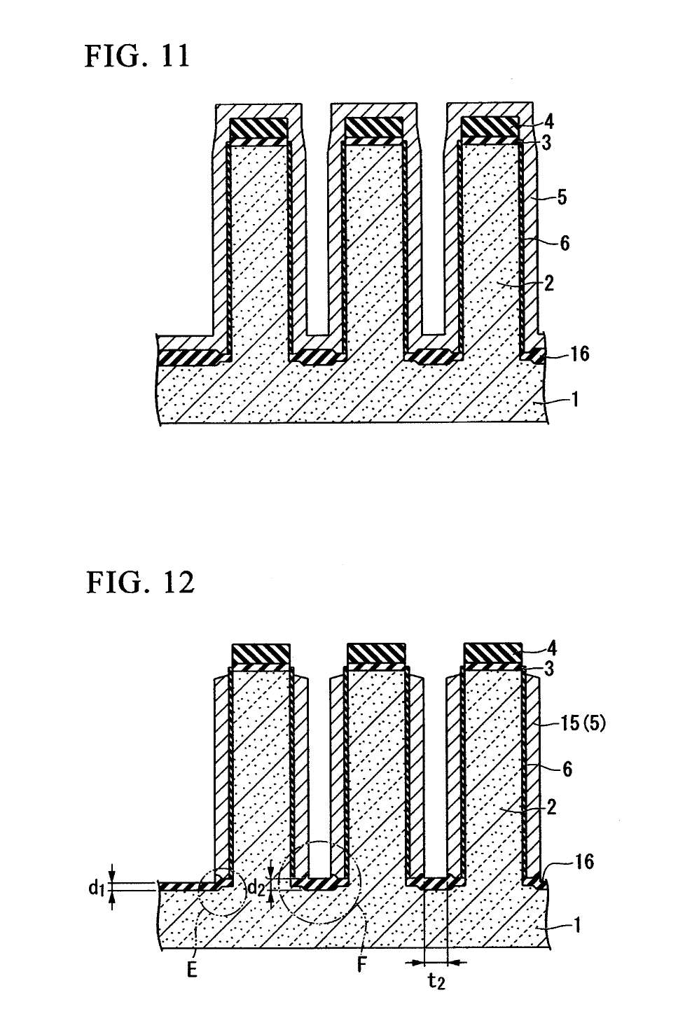

In the eighth process, the conductive film 5 is formed so as to cover the second insulating film 16 covering the surface 1a of the substrate 1 and the side surface 2c of the pillar portion 2, and the nitride film 4 covering the top surface of the pillar portion 2, as shown in FIG. 11.

The conductive film 5 is a gate conductive film made of an electrode material for forming a gate electrode, i.e., a metal material, such as a phosphorus (P)-doped silicon (Si) film, a Ni silicide, a TiN film, or a Ru film. The phosphorus (P)-doped silicon (Si) film is formed by LPCVD or the like. The thickness of the conductive film 5 is, for example, 15 nm.

Then, the conductive film 5 is etched back by anisotropic dry etching until the nitride film 4 covering the top surface of the pillar portion 2 is exposed. The etching of the conductive film 5 is carried out using Cl₂ gas or a mixed gas including Cl₂ gas and O₂ gas. In this case, the second insulating film 16 exposed on the surface 1a of the substrate 1 is also etched.

Thus, the cylindrical conductive layer (gate electrode) 15 including the conductive film 5, which is on the second insulating film 16 and covers the side surface 2c of the pillar portion 2 as a sidewall, is formed.

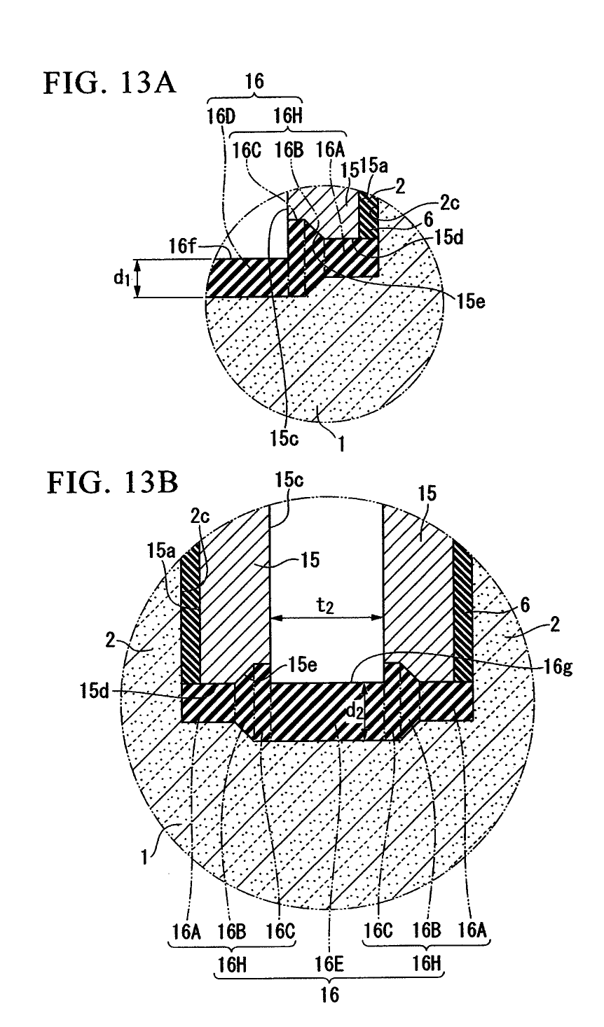

FIG. 13A is an enlarged view illustrating a portion E shown in FIG. 12. As shown in FIG. 13A, the second insulating film 16 in the sparse region 50 includes the thick film portion 16H and the thin film portion 16D.

The thin film portion 16D has a substantially even thickness over the surface 1a of the substrate 1. One end of the thin film portion 16D is connected to the thick film portion 16H, and thus a recessed portion 16f is formed.

The thick film portion 16H includes first to third thick film elements 16C, 16B, and 16A. The first thick film element 16C has an even thickness, which is the thickest among the first to third thick film elements, and is connected to the second thick film element 16B. The thickness of the first thick film element 16C is, for example, 30 nm.

As will be explained later regarding a method of manufacturing the semiconductor device, even if the thickness d₁ of the first thick film element 16C is increased by decreasing the thickness of the recessed portion 16f, the main surface 1a of the substrate 1 is not exposed. Accordingly, the surface 1a of the substrate 1 can be protected, thereby stabilizing the characteristics of the transistor.

The second thick film element 16B is gradually thinner toward the pillar 2, and is connected to the third thick film element 16A. The third thick film element 16A has substantially the same thickness, and is connected to the first insulating film 6. The cross-sectional shape of the second insulating film 16 is called a bird's beak shape since the second insulating film 16 is gradually thicker toward the first thick film element 16C and gradually thinner toward the third thick film element 16A.

FIG. 13B is an enlarged view illustrating a portion F shown in FIG. 12. As shown in FIG. 13B, the second insulating film 16 in the dense region 51 includes the thick film portion 16H and another thin film portion 16E.

Similar to the second insulating film 16 in the sparse region 50, the thick film portion 16H includes first to third thick film elements 16C, 16B, and 16A. The thin film portion 16E has substantially an even thickness over the surface 1a of the substrate 1. Both sides of the thin film portion 16E are connected to the thick film portion 16H, and thus a recessed portion 16g is formed. A thickness d₂ of the thin film portion 16E is larger than a thickness d₁ of the thin film portion 16D.

Generally, the etching rate of the conductive film 5 between two adjacent pillar portions in the dense region 51 is smaller than that of the conductive film 5 between two adjacent pillar portions in the sparse region. In the first embodiment, a distance t between two adjacent pillar portions 2 is narrowed to a distance t₂ of approximately 14 nm due to the formation of the conductive layer 15.

Accordingly, etching ions hit against the conductive layer 15 covering the side surface 2c of the pillar portion 2, and therefore hardly reach the side of the substrate 1. For this reason, the etching rate of the bottom portion of the conductive film 5 between the two adjacent pillar portions 2 in the dense region 51 is approximately one third of that of the conductive film 5 in the sparse region 50.

In the first embodiment, 50% over-etching of the conductive film 5 between the two adjacent pillar portions in the dense region 51 is carried out. The 50% over-etching indicates etching under the condition that the conductive film 5 having a thickness of approximately 15 nm is completely etched, and the conductive film 5 is further etched by approximately 7.5 nm. In this case, the conductive film 5 in the sparse region 50 is removed faster than that in the dense region 51, and then 300% or more over-etching of the fifth insulating film 36 is carried out. The 300% over-etching indicates etching under the condition that the conductive film 5 having a thickness of approximately 15 nm is removed, and then the conductive film 5 is further etched by approximately 45 nm.

Since the etching selectivity of the conductive film 5 to the fifth insulating film 36 is approximately 10, the etching amount of the fifth insulating film 36 to the conductive film 5 is approximately one tenth. For this reason, if 50% over-etching of the fifth insulating film 36 is carried out, the conductive film 5 is removed, and further the fifth insulating film 36 (the second insulating film 16) is etched by approximately 0.75 nm.

If 300% over-etching of the fifth insulating film 36 is carried out, the conductive film 5 is removed, and further the fifth insulating film 36 is etched by approximately 4.5 nm. Accordingly, the thickness d₁ of the thin film portion 16D is approximately 18.5 nm, and the thickness d₂ of the thin film portion 16E is approximately 22.25 nm. Thus, the second insulating film 16 remains covering the surface 1a of the substrate 1, thereby preventing the surface 1a of the substrate 1 from being uneven after being etched.

Then, the nitride film 4 covering the top surface of the pillar portion 2 is removed using, for example, phosphorus. If the nitride film 4 is removed at the same time with the removal of the sidewall 17 covering the side surface 2c of the pillar portion 2 in the process shown in FIG. 9, this process is unnecessary.

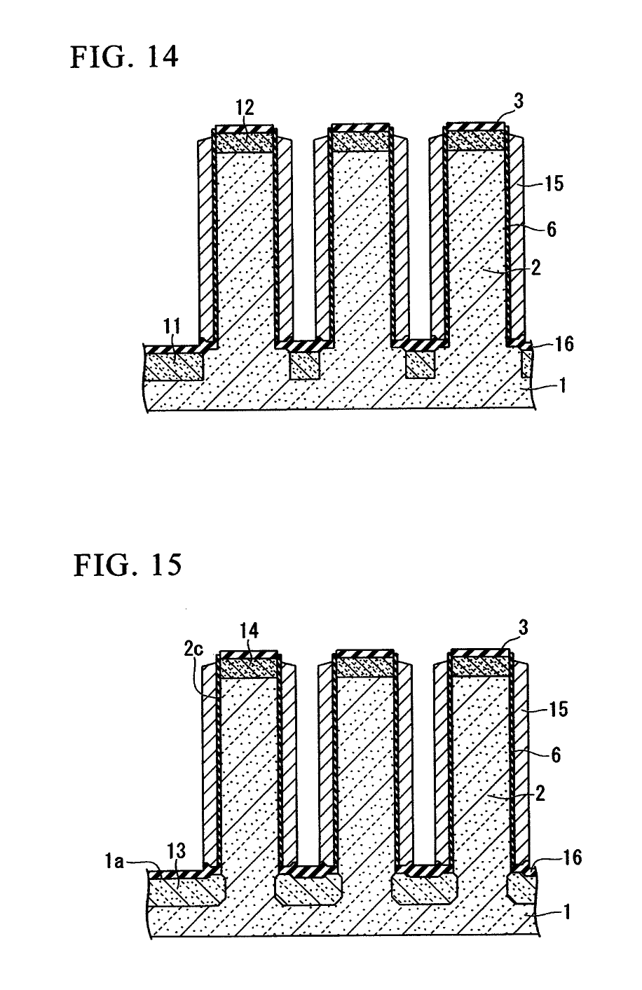

Then, an impurity ion is doped by ion implantation into the upper region of the pillar portion 2 to form an impurity diffusion region 12 as shown in FIG. 14. Additionally, an impurity ion is doped into the substrate 1 immediately under the surface 1a thereof to form an impurity diffusion region 11. Since the conductive layer 15 serves as a mask, the impurity ion is not doped through the side surface 2c of the pillar portion 2.

When an NMOS(N-type MOS transistor) is formed, arsenic (As) ion is doped by ion implantation at an energy of 60 KeV, at a dose of 1×10¹⁴ atoms/cm² to 5×10¹⁵ atoms/cm², or phosphorus (P) ion is doped by ion implantation at an energy of 40 KeV, at a dose of 1×10¹⁴ atoms/cm² to 5×10¹⁵ atoms/cm².

When a PMOS (P-type MOS transistor) is formed, a boron (B) ion is doped by ion implantation at an energy of 15 KeV, at a dose of 1×10¹⁴ atoms/cm² to 5×10¹⁵ atoms/cm². The energy value is a value for doping the impurity ion into a region deeper than the second insulating film 16. By varying the energy value, a doped position of the impurity ion can be determined.

The formation of the impurity diffusion regions 11 and 12 is not limited to this process, and may be carried out in another process. For example, the impurity diffusion region 11 may be formed after the second insulating film 16 shown in FIG. 8 is formed.

Then, a thermal treatment is carried out to activate the impurity diffusion regions 11 and 12, and therefore to form the activated impurity diffusion regions 13 and 14. The impurity ion is self-aligned in the activated impurity diffusion regions 13 and 14 with respect to the conductive layer 15. The activated impurity diffusion regions 13 and 14 are connected to respective power sources to be source/drain regions.

Finally, inter-layer insulating films, contact plugs, wires, and the like are formed, and thus a semiconductor device including a vertical MOS transistor is manufactured.

According to the semiconductor device of the first embodiment, a gate electrode can be formed without etching the main surface of the substrate in the sparse region, thereby stabilizing the characteristics of the transistor.

### Second Embodiment

FIG. 15 is a cross-sectional view illustrating a semiconductor device according to a second embodiment of the present invention. The semiconductor device of the second embodiment has a similar structure as that of the semiconductor device of the first embodiment except that the activated impurity diffusion regions 13 and 14 are formed larger. Like reference numerals denote like elements in the first and second embodiments.

The pillar portion 2 vertically protrudes from the surface 1a of the substrate 1. For this reason, many crystalline defects are expected to occur at a connection portion where the pillar portion 2 is connected to the surface 1a of the substrate 1. As in the second embodiment, however, the impurity diffusion region 13 is formed deeper than that in the first embodiment so as to diffuse in the substrate 1 toward the pillar portion 2. Thus, the connection portion can be protected, only the pillar portion 2 serves as a channel, and thereby junction leakage can be prevented.

Also in the second embodiment, the activated impurity diffusion region 14 is formed deeper than that in the first embodiment, thereby stabilizing the characteristics of the transistor included in the semiconductor device.

Hereinafter, a method of manufacturing the semiconductor device of the second embodiment is explained. The method of the second embodiment is similar to that of the first embodiment except that a time for a thermal treatment for activating an impurity ion is set longer.

The longer time for a thermal treatment for activating an impurity ion enables the impurity ion to diffuse in the substrate 1 and the pillar 2 in the wider range, thereby enabling the activated impurity diffusion region 13 to diffuse toward the pillar portion 2.

### Third Embodiment

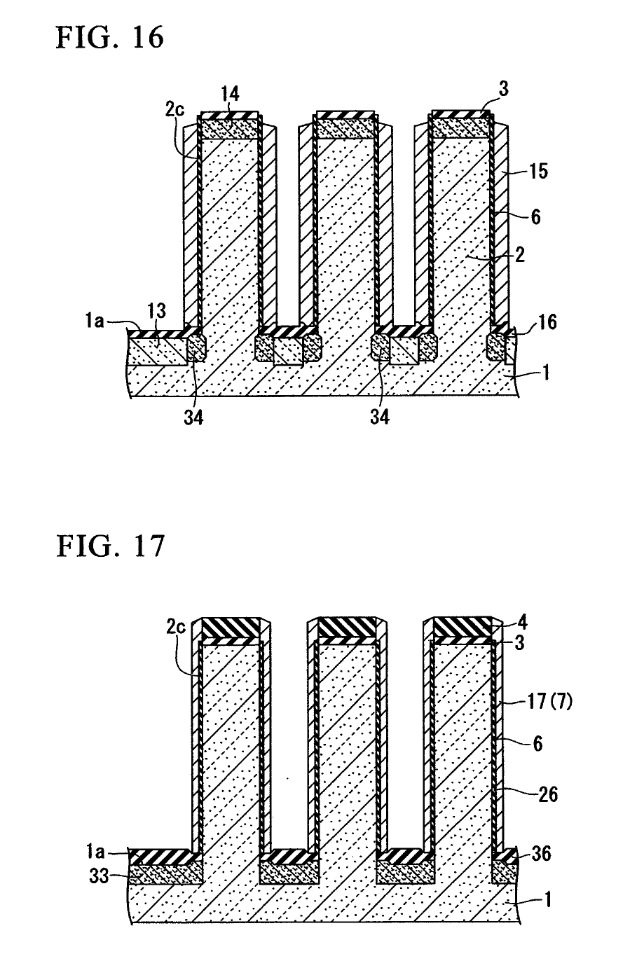

FIG. 16 is a cross-sectional view illustrating a semiconductor device according to a third embodiment of the present invention. The semiconductor device of the third embodiment has a similar structure except that an activated impurity diffusion region 34 is formed on the bottom side of the pillar portion 2.

The structure of the semiconductor device of the third embodiment shown in FIG. 16 is an example of an LDD (Lightly Doped Drain) structure, i.e., the structure of a vertical MOS transistor whose source/drain regions on the side of the substrate 1 has the LDD structure.

The LDD structure is a structure in which a region (n⁻ layer) having a concentration that is smaller by one digit or more is formed between an n⁺ layer and an i layer, thereby enabling a decrease in the field of the drain region. In the third embodiment, the activated impurity diffusion region 34 is the region having a concentration that is smaller by one digit or more.

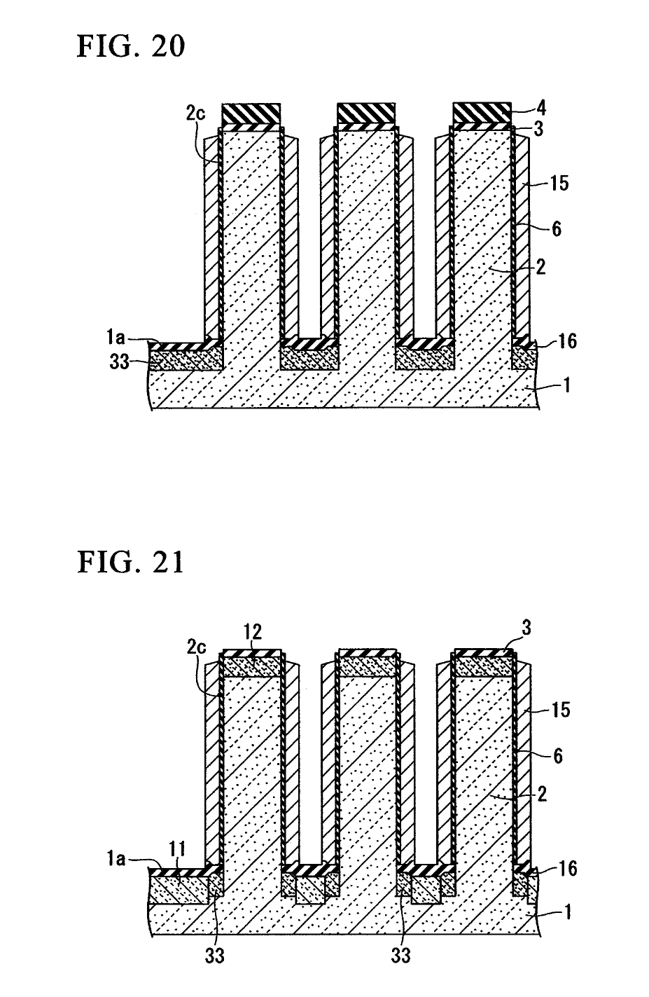

Hereinafter, a method of manufacturing the semiconductor device of the third embodiment is explained with reference to FIGS. 17 to 21. The method of the third embodiment is similar to that of the first embodiment except that a process of forming the impurity diffusion region 34 is added.

In a similar manner as the processes shown in FIGS. 3 to 8 of the first embodiment, the semiconductor device shown in FIG. 8 is formed. Then, an impurity ion is doped by ion implantation into the substrate 1 immediately under the surface 1a thereof using the sidewall 17 (7) as a mask to form an impurity diffusion region 33, as shown in FIG. 17.

The impurity ion is doped in a similar manner as in the first embodiment. However, a concentration of the impurity ion is smaller by one digit or more. For example, when an NMOS is formed, arsenic (As) ion is doped by ion implantation at an energy of 60 KeV, at a dose of 5×10¹² atoms/cm² to 5×10¹⁵ atoms/cm², or phosphorus (P) ion is doped by ion implantation at an energy of 40 KeV, at a dose of 5×10¹² atoms/cm² to 5×10¹⁵ atoms/cm². When a PMOS is formed, boron (B) ion is doped by ion implantation at an energy of 15 KeV, at a dose of 5×10¹² atoms/cm² to 5×10¹⁵ atoms/cm².

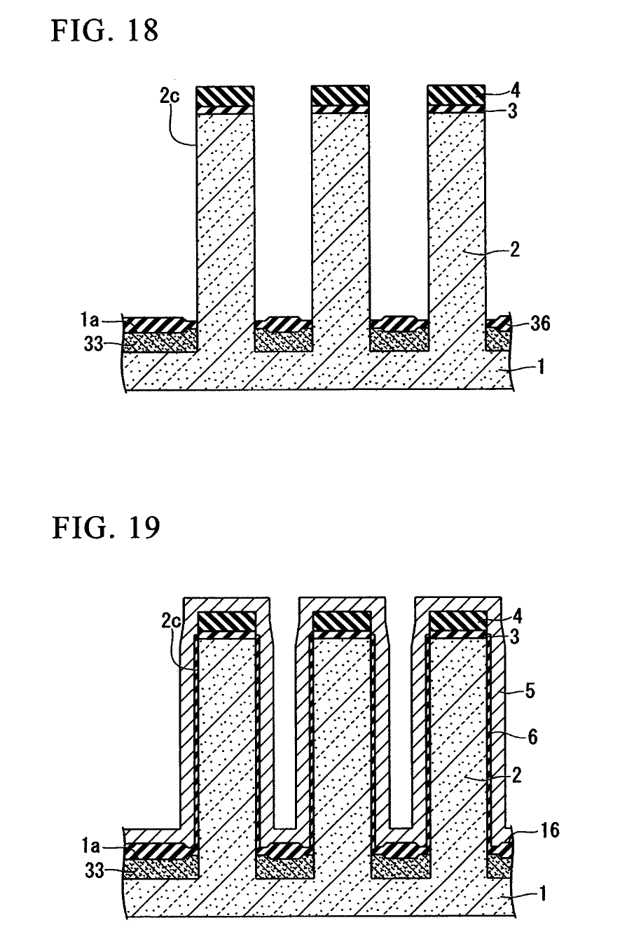

Then, the sidewall 17 covering the side surface 2c of the pillar portion 2 is removed by etching. Then, in a similar manner as explained in the first embodiment, the third insulating film 26 covering the side surface 2c of the pillar portion 2 is removed by dry etching (chemical dry etching or chemical vapor dry etching), as shown in FIG. 18.

In this case, the fifth insulating film 36 covering the surface 1a of the substrate 1 is also etched to be thinner. Since an impurity ion, such as phosphorus (P) ion, is doped in the fifth insulating film 36, and therefore the etching resistance is decreased, the etching rate of the fifth insulating film 36 is 1.2 to 2 times greater. For this reason, the fifth insulating film 36 is etched by 10 nm more than that in the case of the first embodiment, and consequently the thickness of the fifth insulating film 36 is approximately 10 nm.

Then, the first insulating film 6 is formed so as to cover the side surface 2c of the pillar portion 2. For example, a thermal oxide film formed by heating in H₂—O₂ atmosphere at approximately 750° C., or a High-K insulating film (HfSiON or the like) formed by ALD is used as the first insulating film 6. In this case, the fifth insulating film 36 and the first insulating film 6 deposited on the fifth insulating film 36 form the second insulating film 16.

Then, the conductive film 5 is formed so as to cover the second insulating film 16 covering the surface 1a of the substrate 1, the first insulating film 6 covering the side surface 2c of the pillar portion 2, and the nitride film 4 covering the top surface of the pillar portion 2, as shown in FIG. 19.

For example, a phosphorus (P)-doped silicon (Si) film formed by LPCVD or a metal material, such as a Ni silicide, a TiN film, or a Ru film, is used as the conductive film 5. The thickness of the conductive film 5 is, for example, 15 nm.

Then, the conductive film 5 is etched back by anisotropic dry etching until the nitride film 4 covering the top surface of the pillar portion 2 is exposed. The etching of the conductive film 5 is carried out using Cl₂ gas or a mixed gas including Cl₂ gas and O₂ gas. Thus, the conductive film 5 covering the side surface 2c of the pillar portion 2 remains as a sidewall, and the cylindrical conductive layer 15 is formed. At the same time, the exposed portion of the second insulating film 16 is also etched.

Then, the nitride film 4 covering the top surface of the pillar portion 2 is removed. Then, an impurity ion is doped by ion implantation into the upper region of the pillar portion 2 to form the impurity diffusion region 12 as shown in FIG. 21. Additionally, an impurity ion is doped into the substrate 1 immediately under the surface 1a thereof to form the impurity diffusion region 11. Since the conductive layer 15 serves as a mask, the impurity ion is not doped through the side surface 2c of the pillar portion 2.

In this case, an ion is doped so that the impurity ion concentration of the impurity diffusion region 33 is greater than that of the impurity diffusion region 11. For example, when an NMOS(N-type MOS transistor) is formed, arsenic (As) ion is doped by ion implantation at an energy of 60 KeV, at a dose of 1×10¹⁴ atoms/cm² to 5×10¹⁵ atoms/cm², or phosphorus (P) ion is doped by ion implantation at an energy of 40 KeV, at a dose of 1×10¹⁴ atoms/cm² to 5×10¹⁵ atoms/cm². When a PMOS (P-type MOS transistor) is formed, boron (B) ion is doped by ion implantation at an energy of 15 KeV, at a dose of 1×10¹⁴ atoms/cm² to 5×10¹⁵ atoms/cm².

Further, the ion implantation is carried out so that the impurity diffusion region 33 diffuses under the surface 1a of the substrate 1 toward the bottom side of the pillar portion 2 and that the impurity diffusion region 11 diffuses only under the surface 1a of the substrate 1. In other words, the ion implantation is carried out so that the impurity diffusion region 33 diffuses in a wider range than the impurity diffusion region 11 do, and thereby reaches the bottom portion of the pillar portion 2. Thus, the impurity diffusion region 33 remains between the impurity diffusion region 11 and the bottom portion of the pillar portion 2.

Then, a thermal treatment is carried out to activate the impurity diffusion regions 11, 12, and 33, and therefore to form the activated impurity diffusion regions 13, 14, and 34, respectively, as shown in FIG. 16. The impurity ion is self-aligned in the activated impurity diffusion regions 13, 14, and 34 with respect to the conductive layer 15.

Accordingly, the vertical MOS transistor having the LDD structure on the bottom side of the pillar portion 2 can be formed, thereby decreasing the field around the boundary between the channel region and the impurity diffusion region, and therefore stabilizing the characteristics of the semiconductor device.

Although the nitride film 4 covering the top surface of the pillar portion 2 remains when the sidewall 17 (7) is removed in the third embodiment, the nitride film 4 may be removed at the same time. By the nitride film 4 being removed, the LDD structure can be also formed on the top side of the pillar portion 2.

If the nitride film 4 is removed, an impurity ion can be doped into the substrate 1 immediately under the surface 1a and into the top region of the pillar portion 2 at the same time in the process of forming the impurity diffusion region 33. In a similar manner as explained in the first embodiment, the impurity diffusion regions 11 and 12 are formed, and thereby a semiconductor device having the LDD structure on both the top and bottom sides of the pillar portion 2.

A combination of the impurity ion concentration and the ion-doped region is not limited to the above example, and various modifications can be appropriately made according to processes of manufacturing a semiconductor device.

According to the semiconductor device of the third embodiment, a short channel can be achieved. Further, the channel length can be efficiently controlled to enhance the characteristics of the transistor.

### Fourth Embodiment

A semiconductor device according to a fourth embodiment of the present invention has a similar structure as that of the third embodiment except that an impurity ion is doped into the second insulating film 16.

The semiconductor device shown in FIG. 8 is formed first in a similar manner as the processes of the first embodiment shown in FIGS. 3 to 8. Then, an impurity ion is doped, by ion implantation under the same condition as that of the third embodiment, into the substrate 1 immediately under the surface 1a thereof using the sidewall 17 (7) as a mask to form the impurity diffusion region 11. In this case, an impurity having a concentration that is smaller by two or three digits than that of the impurity ion doped into the impurity diffusion region 11 is doped into the second insulating film 16 at the same time.

Then, the sidewall 17 covering the side surface 2c of the pillar portion 2 is removed. The sidewall 17 is made of the insulating film 7. If a nitride film is used as the insulating film 7, the sidewall 17 can be removed using phosphorus or the like.

Then, only the insulating film 26 covering the side surface 2c of the pillar portion 2 is selectively removed using dry etching (chemical dry etching or chemical vapor dry etching). The dry etching is carried out with NH₃/HF=100 sccm/100 sccm, at a pressure of 60 mT, at a stage temperature of 30° C., for a processing time of 90 sec. Subsequently, the dry etching is carried out in N₂ atmosphere, at a pressure of 1 Torr, at a temperature of 200° C., for a processing time of 60 sec.

By an impurity ion 40 being doped into the second insulating film 16, the second insulating film 16 is prevented from being over-etched when vapor etching using HF and NH₃ is carried out in the next process, and thereby the second insulating film, which is thicker, can remain. For example, even if the insulating film 26 having the thickness of approximately 5 nm is removed, a decrease in thickness of the second insulating film 16 can be less than approximately 10 nm. This is because the etching rate of a film into which an impurity ion is doped is smaller than the etching rate of a film into which an impurity ion is not doped regarding vapor etching using HF and NH₃.

The structure of the fourth embodiment is effective especially for further miniaturized semiconductor devices. This is because if a substrate of a further-miniaturized semiconductor device is oxidized to form a thermal oxide film having a thickness of approximately 30 nm or more in narrow space, such as approximately 30 nm or less space, between two adjacent pillar portions after the sidewall 17 is formed, the defects of the substrate occur, thereby making it difficult to form the second insulating film 16 thicker. The structure of the fourth embodiment is applicable to the case where space between the two adjacent pillar portions is narrower with further miniaturization of semiconductor devices.

According to the fourth embodiment, a gate electrode can be formed without etching the main surface of the substrate in the sparse region, thereby stabilizing the characteristics of the transistor.

### Fifth Embodiment

A semiconductor device according to a fifth embodiment of the present invention has a similar structure as that of the first embodiment except that the impurity ion 40 is doped into the fifth insulating film 36 (second insulating film 16).

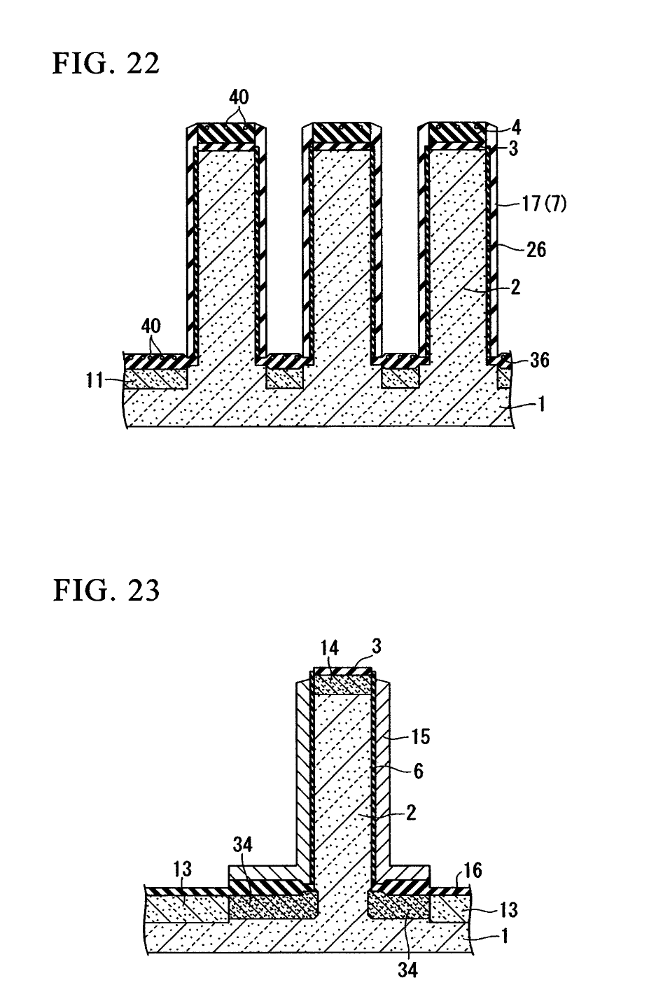

FIG. 22 is a cross-sectional view illustrating one process. The semiconductor device shown in FIG. 8 is formed first in a similar manner as in the processes of the first embodiment shown in FIGS. 3 to 8.

Then, an impurity ion is doped, by ion implantation under the same condition as that of the first embodiment, into the substrate 1 immediately under the surface 1a thereof using the sidewall 17 (7) as a mask to form the impurity diffusion region 11.

Then, the impurity ion 40 is doped into the fifth insulating film 36 and the nitride film 4 as shown in FIG. 22 by ion implantation under substantially the same condition as that of the first embodiment. However, it is required to decrease energy. Accordingly, an ion can be doped into a shallower region, and thereby the impurity ion 40 can be doped into the fifth insulating film 36 and the nitride film 4.

For example, arsenic (As) ion is doped by ion implantation at an energy of 5 KeV, at a dose of 1×10¹³ atoms/cm² to 5×10¹⁵ atoms/cm², phosphorus (P) ion is doped by ion implantation at an energy of 5 KeV, at a dose of 1×10¹³ atoms/cm² to 5×10¹⁵ atoms/cm², or boron (B) ion is doped by ion implantation at an energy of 5 KeV, at a dose of 1×10¹³ atoms/cm² to 5×10¹⁵ atoms/cm². Kinds of impurity ions are not limited thereto, another ion can be used if not affecting the characteristics of the transistor.

Then, the sidewall 17 covering the side surface 2c of the pillar portion 2 is removed. The sidewall 17 is made of the insulating film 7. If a nitride film is used as the insulating film 7, the sidewall 17 can be removed using phosphorus or the like.

Then, the insulating film 26 covering the side surface 2c of the pillar portion 2 is removed using dry etching (chemical dry etching or chemical vapor dry etching). The dry etching is carried out with NH₃/HF=100 sccm/100 sccm, at a pressure of 60 mT, at a stage temperature of 30° C., for a processing time of 90 sec. Subsequently, the dry etching is carried out in N₂ atmosphere, at a pressure of 1 Torr, at a temperature of 200° C., for a processing time of 60 sec.

By the impurity ion 40 being doped into the fifth insulating film 36, the fifth insulating film 36 is prevented from being over-etched when vapor etching using HF and NH₃ is carried out in the next process. For example, even if the insulating film 26 having the thickness of approximately 5 nm is removed, a decrease in thickness of the fifth insulating film 36 can be less than approximately 10 nm. This is because the etching rate of a film into which an impurity ion is doped is smaller than the etching rate of a film into which an impurity ion is not doped regarding vapor etching using HF and NH₃.

The structure of the fifth embodiment is effective especially for further miniaturized semiconductor devices. This is because if a substrate of a further-miniaturized semiconductor device is oxidized to form a thermal oxide film having a thickness of approximately 30 nm or more in narrow space, such as approximately 30 nm or less space, between two adjacent pillar portions after the sidewall 17 is formed, the defects of the substrate occur, thereby making it difficult to form the second insulating film 16 thicker. The structure of the fourth embodiment is applicable to the case where space between the two adjacent pillar portions is narrower with further miniaturization of semiconductor devices.

According to the semiconductor device of the fifth embodiment, a variation of the etching rate is prevented, thereby stabilizing the characteristics of the transistor. Further, a gate electrode can be formed without etching the main surface of the substrate in the sparse region, thereby stabilizing the characteristics of the transistor.

### Sixth Embodiment

FIG. 23 is a cross-sectional view illustrating a semiconductor device of the sixth embodiment of the present invention. The semiconductor device of the sixth embodiment has a similar structure as that of the second embodiment except that the conductive layer includes a sidewall portion covering the side surface 2c of the pillar portion 2 and a substantially-ring shaped portion covering the second insulating film 16 close to the pillar portion 1.

As shown in FIG. 23, the conductive layer 15 has an L-shape in cross-sectional view taken along a plane perpendicular to the surface 1a of the substrate 1. The sidewall portion of the conductive layer 15 serves as a gate electrode similarly to the first embodiment. The ring-shaped portion can stably support the gate electrode.

Hereinafter, a method of manufacturing the semiconductor device of the sixth embodiment is explained. The semiconductor device shown in FIG. 19 is formed first in a similar manner as explained in the third embodiment. Then, a mask covering the conductor layer 15 is formed by lithography over the conductive film 5.

Then, the exposed conductive film 5 is etched until the nitride film 4 covering the top surface of the pillar portion 2 is exposed. In this case, the second insulating film 16 is also etched, and thus the recessed portions 16f and 16g are formed.

Then, the nitride film 4 is removed in a similar manner as explained in the first embodiment. Then, an impurity ion is doped to form the impurity diffusion regions. Then, a thermal treatment is carried out to form the activated impurity diffusion regions 13, 14, and 34, and thus the semiconductor device shown in FIG. 23 is formed.

According to the semiconductor device of the sixth embodiment, a gate electrode can be formed without etching the main surface of the substrate in the sparse region, thereby stabilizing the characteristics of the transistor and stably supporting the gate electrode.

### Comparison Example 1

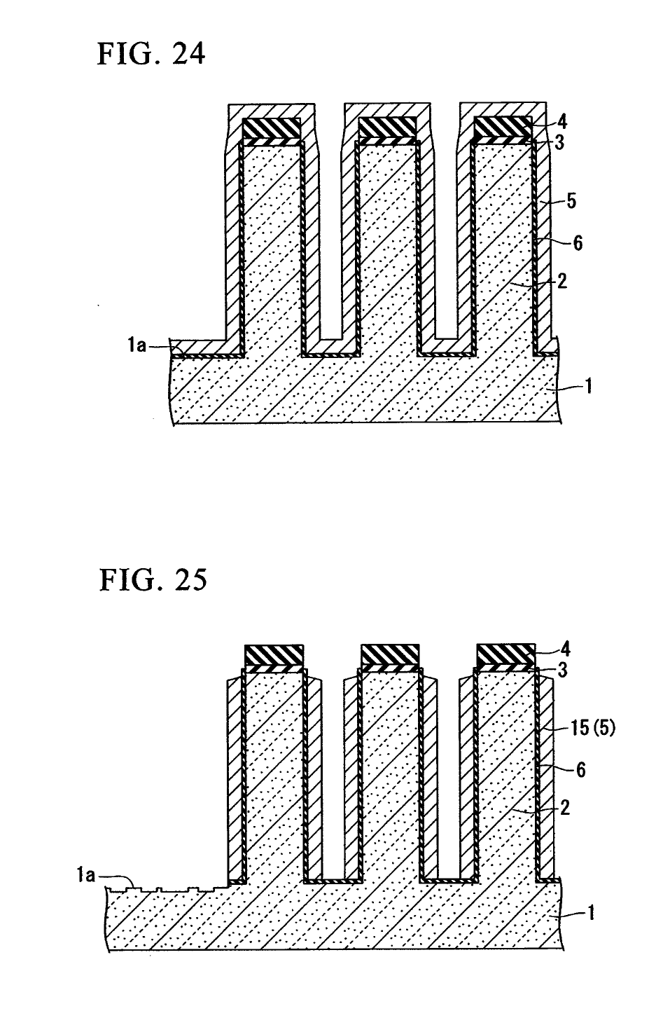

FIGS. 24 and 25 are cross-sectional views illustrating comparison examples regarding a semiconductor device manufacturing method. FIG. 24 is a cross-sectional view after the conductive film 5 was formed. FIG. 25 is a cross-sectional view after the conductive film 5 was etched back to form the conductive layer 15.

The pillar portion 2 was formed, and then the first insulating film 6 was formed so as to cover the pillar portion 2 in a similar manner as explained in the first embodiment. Then, the conductive film 5 was formed so as to cover the first insulating film 6. Thus, the semiconductor device shown in FIG. 24 was formed.

Then, the conductive film 5 was etched back until the nitride film 4 covering the top surface of the pillar portion 2 was exposed and until the conductive film 6 between the two adjacent pillar portions in the dense region was removed. Thus, the semiconductor device including the conductive layer 15 in a sidewall shape was formed as shown in FIG. 25.

As shown in FIG. 25, a region distanced from the pillar portion 2, i.e., a region where the pillar portion 2 was not formed, was over-etched. The first insulating film 6 was removed, and the surface 1a of the substrate 1 was etched until the surface 1a was uneven.

The present invention is applicable to semiconductor device manufacturing industries.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to a device equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percent of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a semiconductor substrate comprising a pillar portion extending from a main surface of the semiconductor substrate;
a first insulating film covering a side surface of the pillar portion;
a second insulating film covering the main surface of the semiconductor substrate, the second insulating film being thicker than the first insulating film; and
a conductive layer extending along the first insulating film.

2. The semiconductor device according to claim 1, wherein the semiconductor substrate comprises first and second regions into which first and second impurity ions are doped, respectively, the first region being adjacent to an upper surface of the pillar portion, and the second region being adjacent to the main surface of the semiconductor substrate.

3. The semiconductor device according to claim 1, wherein the second insulating film immediately under the conductive layer and the first insulating film comprises first and second insulating portions, the first insulating portion being thicker than the second insulating portion, the second insulating portion being between the pillar portion and the first insulating portion.

4. The semiconductor device according to claim 3, wherein the first insulating portion comprises a tapered portion being tapered to the second insulating portion.

5. The semiconductor device according to claim 3, wherein the second insulating film outside the conductive layer and the first insulating film is thinner than the first insulating portion.

6. The semiconductor device according to claim 1, wherein the conductive layer surrounds the side surface of the pillar portion.

7. The semiconductor device according to claim 1, wherein the conductive layer comprises first and second conductive portions extending along the first and second insulating films, respectively, the first and second conductive portions covering the first and second insulating films, respectively.

8. The semiconductor device according to claim 2, wherein
the semiconductor substrate further comprises a third region in which a third impurity ion is doped,
the third region being adjacent to any one of the first and second regions, and
the first to third regions have first to third impurity concentrations, the third impurity concentration being smaller than the first and second impurity concentrations.

9. The semiconductor device according to claim 1, wherein a fourth impurity ion is doped into the second insulating film.

10. A semiconductor device comprising:
a semiconductor substrate comprising a pillar portion extending from a main surface of the semiconductor substrate;
a first insulating film covering a side surface of the pillar portion;
a conductive layer extending along the first insulating film; and
a second insulating film covering the main surface of the semiconductor substrate, the second insulating film immediately under the conductive layer and the first insulating film comprises first and second insulating portions, the first insulating portion being thicker than the second insulating portion, the second insulating portion being between the pillar portion and the first insulating portion.

11. A method of manufacturing a semiconductor device, comprising:
etching a semiconductor substrate to form a pillar portion extending from a main surface of the etched semiconductor substrate;
forming first and second insulating films, the first insulating film covering a side surface of the pillar portion, the second insulating film covering the main surface of the etched semiconductor substrate, and the second insulating film being thicker than the first insulating film;
forming a conductive film covering the first and second insulating films; and
etching the conductive film to form a conductive layer extending along the first insulating film.

12. The method according to claim 11, wherein forming the first and second insulating films comprises:
forming a third insulating film on the main surface of the etched semiconductor substrate and the side surface of the pillar portion;
forming a sidewall on the third insulating film covering the side surface of the pillar portion to expose a part of the main surface of the etched semiconductor substrate;
oxidizing the main surface of the etched semiconductor substrate to form a fourth insulating film including the third insulating film and an oxide film under the third insulating film;
removing the sidewall;
removing the third insulating film covering the side surface of the pillar portion while having the fourth insulating film remain; and
forming the first insulating film so as to cover the side surface of the pillar portion and the remaining fourth insulating film, the second insulating film including the remaining fourth insulating film and the first insulating film on the remaining fourth insulating film.

13. The method according to claim 12, wherein the sidewall is made of a silicon nitride film, and the oxide film under the third insulating film has a bird's beak shape by oxidizing the main surface of the etched semiconductor substrate.

14. The method according to claim 12, wherein the remaining fourth insulating film is thicker than the first insulating film.

15. The method according to claim 12, further comprising:
doping first and second impurity ions into first and second regions in the semiconductor substrate, respectively, the first region being adjacent to an upper surface of the pillar portion, and the second region being adjacent to the main surface.

16. The method according to claim 12, further comprising:
doping a third impurity ion into the fourth insulating film before removing the sidewall.

17. The method according to claim 12, wherein
forming the third insulating film comprises performing a thermal oxidization or an atomic layer deposition method.

18. The method according to claim 12, wherein removing the third insulating film comprises dry-etching the third insulating film with an HF gas and an NH₃ gas.

19. The method according to claim 11, wherein an over-etching is performed at etching the conductive film.

20. The method according to claim 19, wherein the main surface of the etched semiconductor substrate is covered by the second insulating film after over-etching the conductive film.
